(19) United States
(12) Patent Application Publication
(10) Pub. No.: US 2026/0043876 A1
(43) Pub. Date: Feb. 12, 2026

(54) HALL ELEMENT, HALL SENSOR AND ELECTRONIC DEVICE

(71) Applicant: AAC Technologies Pte. Ltd., Singapore (SG)

(72) Inventors: Pongkit Tai, HK (CN); Kengyu Hsu, Taiwan (CN); Shaowei Lin, Taiwan (CN); Tiongkee Chua, Singapore (SG); Yuanmei Huang, Taiwan (CN)

(21) Appl. No.: 18/801,658

(22) Filed: Aug. 12, 2024

(51) Int. Cl. G01R 33/07

(52) U.S. Cl. CPC G01R 33/07

(57) ABSTRACT

Provided is a Hall element. The Hall element includes a substrate, a Hall-sensing layer disposed on the substrate, electrodes, a blocking layer, and a conductor pad. The electrodes are connected to the Hall-sensing layer. The blocking layer is disposed on a side of the Hall-sensing layer facing away from the substrate and covers the Hall-sensing layer. The conductor pad is disposed on a side of the blocking layer facing away from Hall-sensing layer and configured to be grounded or connected to a predetermined voltage. Applying a potential to the blocking layer covering the Hall sensing layer through the conductor pad not only creates a depletion layer of a sufficient width to limit the current flow direction, thereby producing an effective isolation effect, but also reduces the thickness of the Hall-sensing layer to increase the value of an induced Hall voltage, thereby enhancing the sensitivity of the Hall element.

### TECHNICAL FIELD

The present disclosure relates to the technical field of semiconductors and, in particular, to a Hall element, a Hall sensor, and an electronic device.

### BACKGROUND

Hall sensors have been widely used in engineering fields such as measurement and control. The Hall sensors have the advantages of small size, light weight, long life, low power consumption, low working condition requirements, etc. Moreover, since the Hall sensors use the electromagnetic effect for non-contact measurement, the Hall sensors are able to carry out non-interference measurements on a measured object, which makes the Hall sensors applicable to many special occasions.

A Hall element as a core component of a Hall sensor is critical in the research and design process. Performance parameters of the Hall element include sensitivity, temperature stability, magnetic field strength sensing range and the like, among which the sensitivity is the most core performance parameter objective. The Hall element may be implemented by a variety of structures and processing techniques, but the Hall element with such structures are often either complex and expensive or have low performance parameters, which cannot meet the requirements of practical applications for high sensitivity Hall elements.

### SUMMARY

The present disclosure provides a Hall element, a Hall sensor, and an electronic device, in order to improve the high sensitivity of existing Hall elements.

To solve the above objective, the present disclosure provides a Hall element. The Hall element includes a substrate, a Hall-sensing layer, a plurality of electrodes, a blocking layer, and a conductor pad. The Hall-sensing layer is disposed on the substrate. The plurality of electrodes are connected to the Hall-sensing layer. The blocking layer is disposed on a side of the Hall-sensing layer facing away from the substrate and covers the Hall-sensing layer. The conductor pad is disposed on a side of the blocking layer facing away from Hall-sensing layer and configured to be grounded or connected to a predetermined voltage.

In some embodiment, in response to the Hall-sensing layer being a NWELL layer or a DNW layer, the conductor pad is configured to be grounded; and in response to the Hall-sensing layer being a RW layer, the conductor pad is configured to be connected to the predetermined voltage.

In some embodiment, the Hall-sensing layer includes a central portion and four protrusions, the four protrusions are arranged in a circumferential direction of the central portion and connected to the central portion to form a cross-type structure, and the four protrusions are connected to four electrodes of the plurality of electrodes respectively.

In some embodiment, the Hall-sensing layer further includes triangular connection portions, and each two adjacent protrusions of the four protrusions are connected to each other by a respective triangular connection portion of the triangular connection portions to form an octagonal structure of the Hall-sensing layer.

In some embodiment, the Hall-sensing layer further includes arc-angle connection portions, each two adjacent protrusions of the four protrusions are connected to each other by a respective arc-angle connection portion of the arc-angle connection portions, and a contour line of the respective arc-angle connection portion facing away from the central portion is a circular arc line recessed towards the central portion. A radius of the circular arc line is equal to one-fourth of a protruding length of each of the four protrusions. Alternatively, a radius of the circular arc line is equal to one-half of a protruding length of each of the four protrusions. Alternatively, a radius of the circular arc line is equal to a protruding length of each of the four protrusions.

In some embodiment, the conductor pad includes a first counterpart portion, four second counterpart portions, and four conductor connection portions. The first counterpart portion is disposed proximate to the central portion. The four second counterpart portions are disposed proximate to the four protrusions respectively. Each respective second counterpart portion of the four second counterpart portions is connected to the first counterpart portion by a respective conductor connection portion of the four conductor connection portions.

In some embodiment, the Hall sensing layer includes at least one of a NWELL layer, a TWELL layer, a DNW layer, and a RW layer, a PP layer and a NP layer.

In some embodiment, the blocking layer includes at least one of a PP layer, a RW layer and a NP layer.

In some embodiment, each of a length and a width of the Hall sensing layer is 30 μm to 270 μm.

The present disclosure further provides a Hall sensor. The Hall sensor includes the Hall element described above.

The present disclosure further provides an electronic device. The electronic device includes the Hall sensor described above.

The technical solutions of the present disclosure have at least the following beneficial effects.

In the Hall element in the present disclosure, applying a potential to the blocking layer covering the Hall sensing layer through the conductor pad not only creates a depletion layer of a sufficient width to limit the current flow direction, thereby producing an effective isolation effect, but also reduces the thickness of the Hall-sensing layer to increase the value of an induced Hall voltage, thereby enhancing the sensitivity of the Hall element.

### BRIEF DESCRIPTION OF THE DRAWINGS

One or more embodiments are exemplarily described with reference to the corresponding figures in the accompanying drawings, and the descriptions are not to be construed as limiting the embodiments. Elements in the accompanying drawings that have same reference numerals are represented as similar elements, and unless otherwise particularly stated, the figures in the accompanying drawings are not drawn to scale.

FIG. 1 is a top view of a Hall element of a first embodiment of the present disclosure.

FIG. 2 is a sectional view of the Hall element of the first embodiment of the present disclosure.

FIG. 3 is a top view of a Hall-sensing layer of the first embodiment of the present disclosure.

FIG. 4 is a sectional view of a Hall element of a second embodiment of the present disclosure.

FIG. 5 is a sectional view of a Hall element of a third embodiment of the present disclosure.

FIG. 6 is a top view of a Hall-sensing layer of a fourth embodiment of the present disclosure.

FIG. 7 is a top view of a Hall-sensing layer of a fifth embodiment of the present disclosure.

FIG. 8 is a top view of a Hall-sensing layer of a sixth embodiment of the present disclosure.

### DETAILED DESCRIPTION OF THE EMBODIMENTS

To make the objects, technical solutions and advantages of the present disclosure clearer, embodiments of the present disclosure are described in detail below in conjunction with the accompanying drawings. Those of ordinary skill in the art should appreciate that in embodiments of the present disclosure, numerous technical details have been presented to enable better understanding of the present disclosure. However, even without these technical details and various variations and modifications based on the following embodiments, the technical solutions claimed in the present disclosure can be realized.

In embodiments of the present disclosure, the terms “on,” “below,” “left,” “right,” “front,” “back,” “top,” “bottom,” “inside,” “outside,” “middle,” “vertical,” “horizontal,” “transverse,” “longitudinal,” and the like indicate orientation or positional relationships based on the accompanying drawings. These terms are intended primarily to better describe the present disclosure and embodiments thereof and are not intended to limit that the indicated device, element or component must have a particular orientation or be constructed and operated in a particular orientation.

Further, some of the above terms may be used to indicate other meanings in addition to the orientation or positional relationships. For example, the term “on” may also be used to indicate a certain attachment or connection relationship in some cases. For those of ordinary skill in the art, specific meanings of the terms in the present disclosure may be construed according to specific circumstances.

In addition, the terms “mounted,” “disposed,” “provided,” “opened,” “connected” and “connected to each other” should be understood in a broad sense. For example, the term “connected” may refer to “securely connected,” “detachably connected” or “monolithically connected”; may refer to “mechanically connected” or “electrically connected”; and may refer to “connected directly,” “connected indirectly through an intermediary” or “interconnected between two devices, elements or components”. For those of ordinary skill in the art, specific meanings of the preceding terms in the present disclosure may be construed according to specific circumstances.

In addition, the terms “first,” “second,” etc. are mainly used to distinguish different devices, elements or components (the specific types and configurations may be the same or different), and are not used to indicate or imply the relative importance and number of the indicated devices, elements or components. Unless otherwise indicated, “plurality” means two or more.

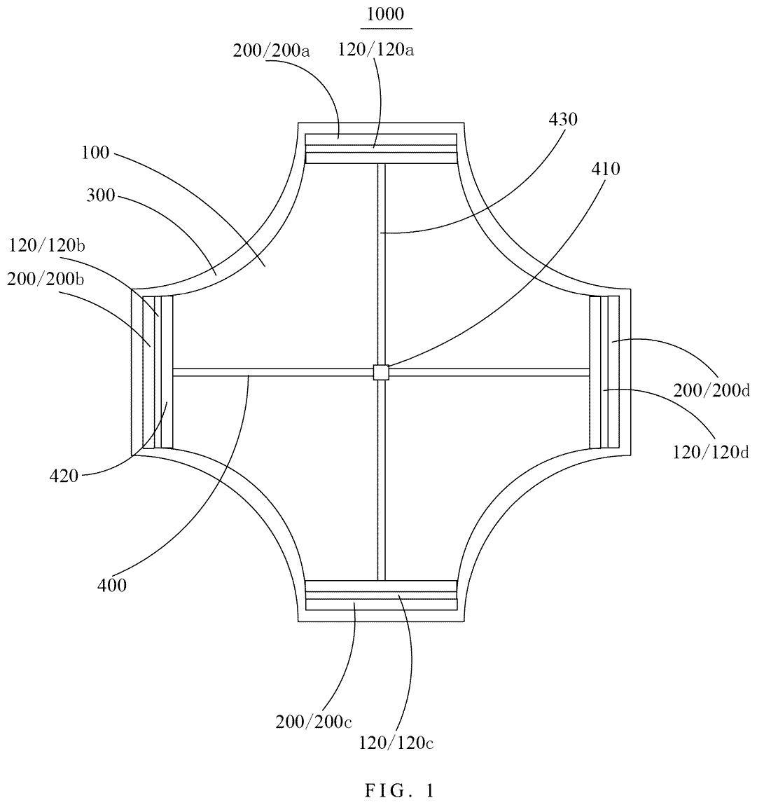

The embodiments of the present disclosure provide a Hall element. FIGS. 1 to 3 illustrate a Hall element according to an embodiment of the present disclosure. Referring to FIGS. 1 to 3, the Hall element 1000 includes a substrate 500, a Hall-sensing layer 100, a plurality of electrodes 200, a blocking layer 300, and a conductor pad 400. The Hall-sensing layer 100 is disposed on the substrate. The plurality of electrodes 200 are connected to the Hall-sensing layer 100. The blocking layer 300 is disposed on a side of the Hall-sensing layer 100 facing away from the substrate. The blocking layer 300 covers the Hall-sensing layer 100. The conductor pad 400 is disposed on a side of the blocking layer 300 facing away from the Hall-sensing layer 100, and is configured to be grounded or connected to a predetermined voltage.

In the Hall element 1000 in the present disclosure, applying a potential to the blocking layer 300 covering the Hall sensing layer 100 through the conductor pad 400 not only creates a depletion layer of a sufficient width to limit the current flow direction, thereby producing an effective isolation effect, but also reduces the thickness of the Hall-sensing layer 100 to increase the value of an induced Hall voltage, thereby enhancing the sensitivity of the Hall element 1000.

The Hall element 1000 may be fabricated in a standard complementary metal oxide semiconductor (CMOS) process. The Hall element 1000 includes the substrate, the specific shape of which may not be specifically limited. The substrate may have a shape such as a regular octagon, a cross, a rectangle or a square when viewed from the top of the substrate.

The Hall-sensing layer 100 is disposed on a side of the substrate, and the substrate and the Hall-sensing layer 100 are of opposite conductivity types. For example, the Hall-sensing layer 100 may be doped with N-type dopant, and the substrate may be doped with P-type dopant. For another example, the Hall-sensing layer 100 may be doped with P-type dopant, and the substrate may be doped with N-type dopant.

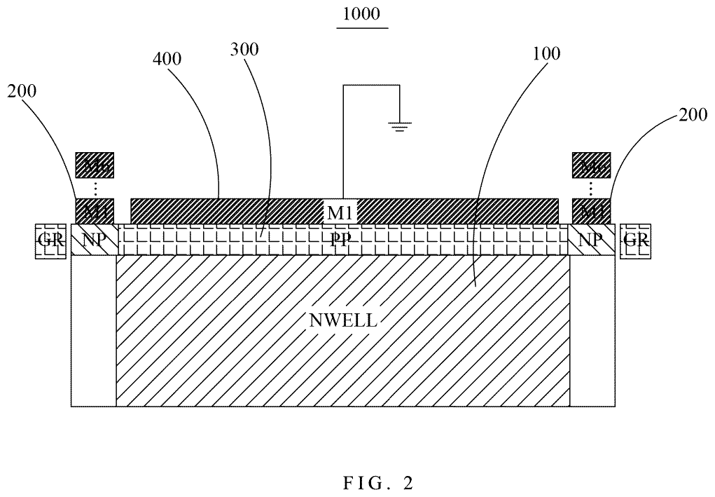

The plurality of electrodes 200 are connected to the Hall-sensing layer 100. With the plurality of electrodes 200, a bias current input to the Hall-sensing layer 100 and a Hall voltage output from the Hall-sensing layer 100 are enabled. The electrode 200 may include one or more metal layers. As shown in FIG. 2A, the electrode 200 includes six metal layers M1 to M6.

The blocking layer 300 is disposed on the side of the substrate proximate to the Hall-sensing layer 100, and the blocking layer 300 covers the Hall-sensing layer 100. The blocking layer 300 covers the Hall-sensing layer 100 with a protection structure as a blocker for blocking a current.

The conductor pad 400 corresponds to the Hall-sensing layer 100, is disposed on the side of the blocking layer 300 facing away from the Hall-sensing layer 100, and is grounded or connected to a voltage source with a preset voltage VDD. The potential is applied to the blocking layer 300 by the conductor pad 400 to create a depletion layer of a sufficient width, thereby producing the effective isolation effect and enhancing the sensitivity of the Hall element 1000 sensing. The conductor pad 400 may include one or more metal layers. As shown in FIG. 2A, the conductor pad includes one metal layer M1.

As can be seen from Equation (1.1), if a potential is applied to the blocking layer 300 on the Hall-sensing layer 100, not only can a depletion region be created to limit the current flow direction, but also the thickness t of the Hall-sensing layer 100 can be reduced to increase the value of the induced Hall voltage VH.

$${V}_{H} = ( {R}_{H} / t ) IB \qquad ( 1.1 )$$

In the above Equation (1.1), R_{H} represents a Hall coefficient, t represents a thickness of the Hall-sensing layer 100, I represents a current magnitude, and B represents a magnetic induction intensity. It can be seen from Equation (1.1) that when the current is increased, the Hall voltage rises with the increase in current, and decreasing the thickness of the Hall-sensing layer 100 also has the same enhanced effect.

The conductor pad 400 is grounded or connected to the preset voltage, and the specific manner in which the potential is applied to the blocking layer 300 via the conductor pad 400 is related to the doping type of the Hall-sensing layer 100. When the doping type of the Hall-sensing layer 100 is N-type doping, the conductor pad 400 is grounded, and when the doping type of the Hall-sensing layer 100 is P-type doping, the conductor pad 400 is connected to a preset voltage VDD.

Optionally, referring to FIGS. 1 to 3, in the first embodiment, the Hall-sensing layer 100 is an N-well (NWELL or NW) layer, and the conductor pad 400 is configured to be grounded.

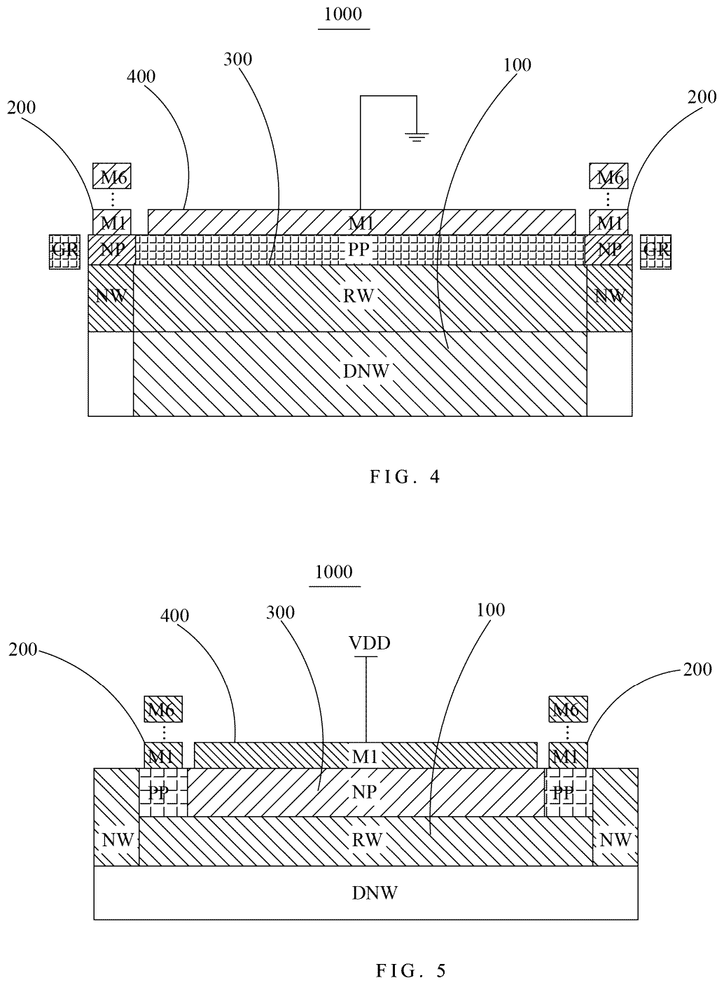

Optionally, referring to FIG. 4, in a second embodiment, the Hall-sensing layer 100 is a deep P-well (DNW) layer, and the conductor pad 400 is configured to be grounded.

Optionally, referring to FIG. 5, in a third embodiment, the Hall-sensing layer 100 is a RW layer, and the conductor pad 400 is configured to be connected to a preset voltage VDD.

The Hall-sensing layer 100 may be specifically set based on the actual situation. The Hall-sensing layer 100 may be at least one of a NWELL layer, a T-well (TWELL) layer, a DNW layer, a RW layer, a P plus (PP) layer and an N plus (NP) layer. Herein, “P plus (PP)” refers to P material implant or P+, and “N plus (NP)” refers to N material implant or P+.

Similarly, the blocking layer 300 may be specifically set based on the actual situation, and the blocking layer 300 may be at least one of a PP layer, a RW layer, and a NP layer. For example, using one of a NWELL layer, a DNW layer and a RW layer as the Hall-sensing layer 100, a PP layer or an NP layer may be used as the blocking layer 300 on the Hall-sensing layer 100. For another example, it is also possible to use one of a PP layer and an NP layer as the Hall-sensing layer 100, and the other of the PP layer and the NP layer as the blocking layer 300.

Optionally, referring to FIGS. 1 to 3, in the first embodiment, the Hall-sensing layer 100 is a NWELL layer, and the blocking layer 300 is a PP layer.

Optionally, referring to FIG. 4, in the second embodiment, the Hall-sensing layer 100 is a DNW layer, the blocking layer 300 includes a RW layer and a PP layer, the RW layer covers the top of the Hall-sensing layer 100, and the PP layer is disposed at a side of the RW layer facing away from the Hall-sensing layer 100.

Optionally, referring to FIG. 5, in the third embodiment, the Hall-sensing layer 100 is a RW layer, the blocking layer 300 includes a NP layer and a PP layer, and the PP layer is disposed on an outer side of the NP layer.

Optionally, referring to FIGS. 1 to 3, in the first embodiment, the Hall-sensing layer 100 includes a central portion 110 and four protrusions 120. The four protrusions 120 are arranged in a circumferential direction of the central portion 110 and connected to the central portion 110 to form a cross-type structure. The four protrusions 120 are connected to four electrodes 200 respectively.

Specifically, ends of the four protrusions 120 facing away from the central portion 110 form a first current source output and input end, a second current source output and input end, a first voltage sensing end, and a second voltage sensing end of the Hall-sensing layer 100 respectively. The four protrusions 120 are hereinafter defined as a first protrusion 120a, a second protrusion 120b, a third protrusion 120c and a fourth protrusion 120d. The first protrusion 120a is disposed opposite to the third protrusion 120c. An end of the first protrusion 120a facing away from the central portion 110 is the first current source output and input end, and an end of the third protrusion 120c facing away from the central portion 110 is the second current source output and input end. The second protrusion 120b is disposed opposite to the fourth protrusion 120d. An end of the second protrusion 120b facing away from the central portion 110 is the first voltage sensing end, and an end of the fourth protrusion 120d facing away from the central portion 110 is the second voltage sensing end.

The four electrodes 200 are a first electrode 200a, a second electrode 200b, a third electrode 200c, and a fourth electrode 200d. The first electrode 200a, the second electrode 200b, the third electrode 200c and the fourth electrode 200d are connected to the first current source output and input end, the first voltage sensing end, the second current source output and input end and the second voltage sensing end of the Hall-sensing layer 100 respectively.

The specific connection mode between the electrode 200 and the Hall-sensing layer 100 may be set according to the actual situation. Optionally, referring to FIGS. 1 to 3, in the first embodiment, an NP layer is disposed on an outer side of the blocking layer 300, and the electrode 200 is connected to the Hall-sensing layer 100 through the NP layer, as shown in FIG. 2B. The Hall-sensing layer 100 is an NWELL layer, and an electrical signal is transmitted from the NP layer to the NWELL layer.

Optionally, referring to FIG. 4, in the second embodiment, the blocking layer 300 includes a RW layer and a PP layer. The RW layer covers the Hall-sensing layer 100, and the PP layer is disposed on a side of the RW layer facing away from the Hall-sensing layer 100. The Hall-sensing layer 100 is a DNW layer, an NWELL layer is disposed on an outer side of the RW layer, and an NP layer is disposed on an outer side of the PP layer. An electrical signal is transmitted to the DNW layer after passing through the NP layer and the NWELL layer in sequence. The NWELL layer is provided in an intermittent manner so that the four electrodes 200 cannot be connected to each other by the NWELL layer.

Optionally, referring to FIG. 5, in the third embodiment, the blocking layer 300 includes an NP layer, and a PP layer disposed on an outer side of the NP layer. The Hall-sensing layer 100 is a RW layer, the electrode 200 is connected to the Hall-sensing layer 100 through the PP layer, and an NWELL layer is disposed on an outer side of the RW layer. An electrical signal is input to the Hall-sensing layer 100 by the PP layer, so the NP layer is adopted as the blocking layer 300, and the NP layer is connected to the highest potential.

The specific size of the Hall-sensing layer 100 may be set according to the actual situation. Optionally, in the first embodiment, each of a length and a width of the Hall-sensing layer 100 is 30 μm to 270 μm. For example, each of the length and the width of the Hall-sensing layer 100 may be 30 μm, 45 μm, 90 μm, 180 μm, or 270 μm.

Optionally, referring to FIGS. 1 to 3, in the first embodiment, the conductor pad 400 includes a first counterpart portion 410, four second counterpart portions 420, and four conductor connection portions 430. The first counterpart portion 410 is disposed proximate to the central portion 110, the four second counterpart portions 420 are disposed proximate to the four protrusions 120 respectively, and each respective second counterpart portion 420 is connected to the first counterpart portion 410 by a respective conductor connection portion 430.

Specifically, the first counterpart portion 410 is opposite to the central portion 110, and generally has a shape matching a shape of the central portion 110. For example, the first counterpart portion 410 may be provided in a square shape. The four second counterpart portions 420 are respectively opposite to the ends of the four protrusions 120 facing away from the central portion 110, and are respectively proximate to the first electrode 200a, the second electrode 200b, the third electrode 200c and the fourth electrode 200d. The second counterpart portions 420 generally have shapes matching shapes of the electrodes 200. For example, the second counterpart portions 420 and the electrodes 200 may all be provided in an elongate shape. The four conductor connection portions 430 are connected to each other by the first counterpart portion 410 to allow the conductor pad 400 to be provided in a cross shape.

As described above, the Hall-sensing layer 100 has a cross-type structure so that the Hall-sensing layer 100 has four corners. In order to avoid excessive concentration of current at the four corners of the Hall-sensing layer 100, optionally, referring to FIGS. 1 to 3, in the first embodiment, the Hall-sensing layer 100 further includes arc-angle connection portions 140. Each two adjacent protrusions 120 are connected to each other by a respective arc-angle connection portion 140, and a contour line of the respective arc-angle connection portion 140 facing away from the central portion 110 is a circular arc line 141 recessed towards the central portion 110.

Specifically, the Hall-sensing layer 100 further includes four arc-angle connection portions 140 disposed at four corners of the Hall-sensing layer 100 respectively, such that the four corners of the Hall-sensing layer 100 form four arc corners, thereby improving the problem of excessive concentration of current at the four corners of the Hall-sensing layer 100.

Further, referring to FIGS. 1 to 3, in the first embodiment, a radius of the circular arc line 141 is equal to a protrusion length of the protrusion 120.

Specifically, each protrusion 120 includes a side line 121 away from the central portion 110, and two connection lines 122 connected between the side line 121 and the central portion 110. The protrusion length of the protrusion 120 is a distance from the side line 121 to the central portion 110, and is also a length of the connecting line 122. The protrusion length of the protrusion 120 is hereinafter defined as d, where a value of d may range from 30 μm to 90 μm. For example, d may be 30 μm, 60 μm, or 90 μm.

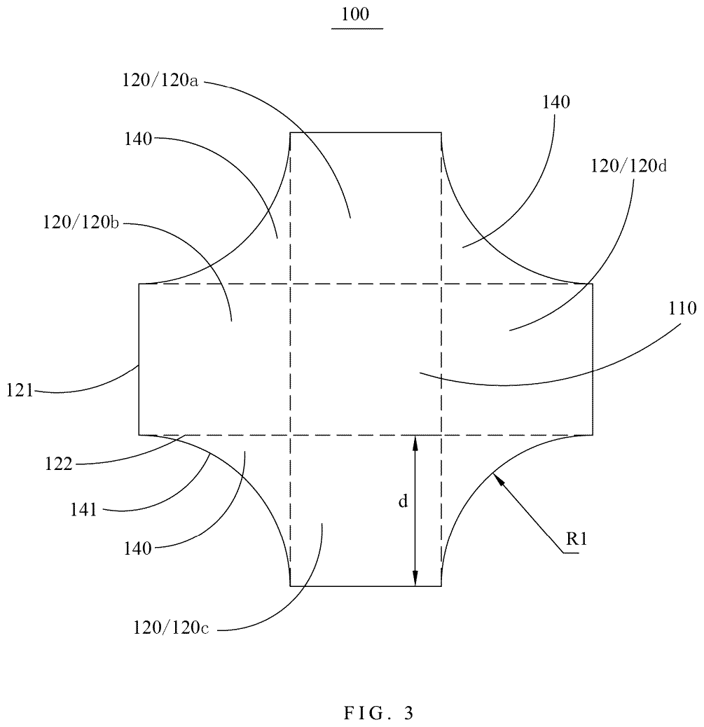

Referring to FIG. 3, in the first embodiment, a radius R1 of the circular arc line 141 is equal to d, and two ends of the circular arc line 141 of each arc-angle connection portion 140 are connected to side lines 121 of two adjacent protrusions 120 respectively.

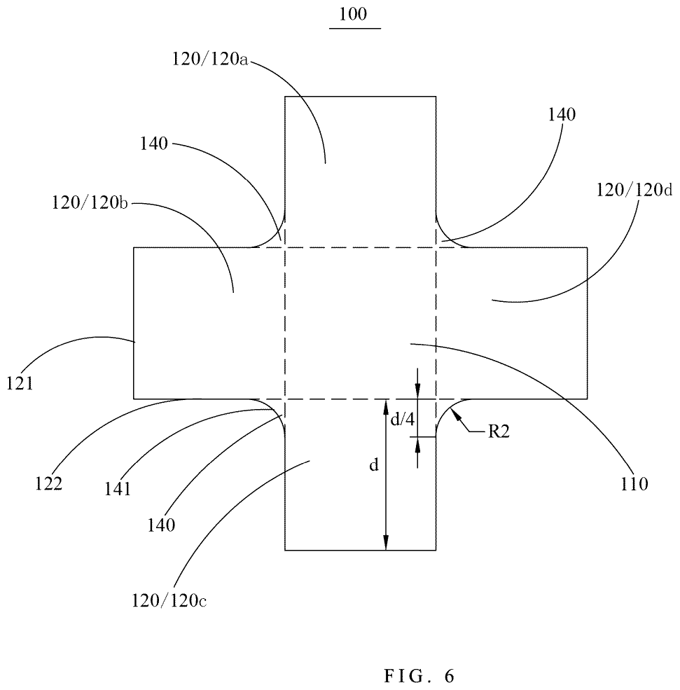

Optionally, referring to FIG. 6, in a fourth embodiment, the radius of the circular arc line 141 is equal to one-quarter of the protrusion length of the protrusion 120.

Specifically, the radius R2 of the circular arc line 141 is equal to d/4, and each of two ends of the circular arc line 141 of each arc-angle connection portion 140 is connected to a respective connection line 122 of connection lines 122 of two adjacent protrusions 120 at a quarter of the respective connection line 122.

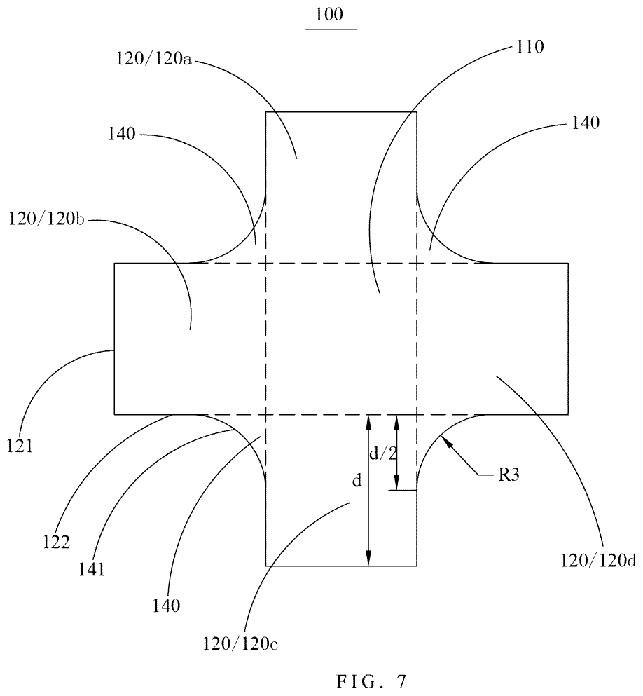

Optionally, referring to FIG. 7, in a fifth embodiment, the radius of the circular arc line 141 is equal to one-half of the protrusion length of the protrusion 120.

Specifically, the radius R3 of the circular arc line 141 is equal to d/2, and each of two ends of the circular arc line 141 of each arc-angle connection portion 140 is connected to a respective connection line 122 of connection lines 122 of two adjacent protrusions 120 at one-half of the respective connection line 122.

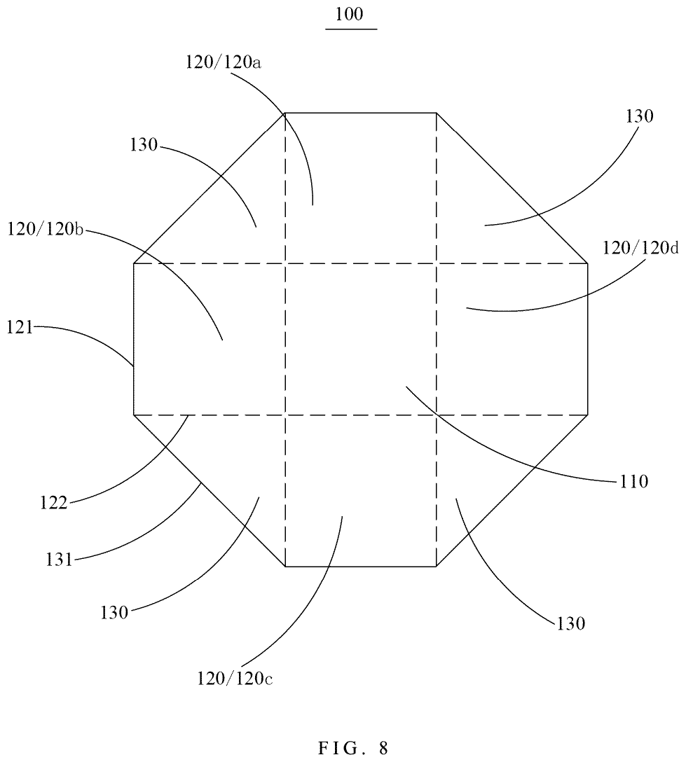

Optionally, referring to FIG. 8, in a sixth embodiment, the Hall-sensing layer 100 further includes triangular connection portions 130, and each two adjacent protrusions 120 are connected to each other by a respective triangular connection portion 130 to form an octagonal structure of the Hall-sensing layer 100.

Specifically, the Hall-sensing layer 100 further includes four triangular connection portions 130 disposed at four corners of the Hall-sensing layer 100. Each triangular connection portion 130 has a slanted edge line 131 facing away from the central portion 110, and two ends of the slanted edge line 131 are connected to edge lines 121 of two adjacent protrusions 120 respectively, so that the Hall-sensing layer 100 is provided in an octagonal shape.

Further, referring to FIG. 8, in a sixth embodiment, a length of the slanted edge line 131 is equal to \sqrt{2}d such that the Hall-sensing layer 100 is provided in a regular octagonal shape.

The present disclosure further provides a Hall sensor including a Hall element. Since the Hall element adopts the technical solutions in the above-described embodiments, the Hall sensor also has the beneficial effects brought about by the technical solutions of the above-described embodiments.

The present disclosure further provides an electronic device. The electronic device may be a smartphone, a tablet computer, a smartwatch, a camera, or the like. The electronic device includes a Hall sensor including a Hall element, and since the Hall element adopts the technical solutions of the above embodiment, the electronic device has the beneficial effects of the technical solutions of the above embodiments.

The above describes the Hall element, Hall sensor and electronic device in the embodiments of the present disclosure in detail, and specific examples are used herein to illustrate the principle and implementations of the present disclosure.

The description of the above embodiments is only intended to help understand the idea of the present disclosure, and changes may be made in the specific embodiments and the scope of the present disclosure. In summary, the contents of this specification should not be construed as limiting the present disclosure.

What is claimed is:

1. A Hall element, comprising:
a substrate;
a Hall-sensing layer, disposed on the substrate;
a plurality of electrodes, connected to the Hall-sensing layer;
a blocking layer, disposed on a side of the Hall-sensing layer facing away from the substrate and covering the Hall-sensing layer; and
a conductor pad, disposed on a side of the blocking layer facing away from Hall-sensing layer and configured to be grounded or connected to a predetermined voltage.

2. The Hall element according to claim 1, wherein in response to the Hall-sensing layer being a N-well (NWELL) layer or a deep N-well (DNW) layer, the conductor pad is configured to be grounded, and in response to the Hall-sensing layer being a RW layer, the conductor pad is configured to be connected to the predetermined voltage.

3. The Hall element according to claim 1, wherein the Hall-sensing layer includes a central portion and four protrusions, the four protrusions are arranged in a circumferential direction of the central portion and connected to the central portion to form a cross-type structure, and the four protrusions are connected to four electrodes of the plurality of electrodes respectively.

4. The Hall element according to claim 3, wherein the Hall-sensing layer further includes triangular connection portions, and each two adjacent protrusions of the four protrusions are connected to each other by a respective triangular connection portion of the triangular connection portions to form an octagonal structure of the Hall-sensing layer.

5. The Hall element according to claim 3, wherein the Hall-sensing layer further includes arc-angle connection portions, each two adjacent protrusions of the four protrusions are connected to each other by a respective arc-angle connection portion of the arc-angle connection portions, and a contour line of the respective arc-angle connection portion facing away from the central portion is a circular arc line recessed towards the central portion, wherein:
a radius of the circular arc line is equal to one-fourth of a protruding length of each of the four protrusions; or
a radius of the circular arc line is equal to one-half of a protruding length of each of the four protrusions; or
a radius of the circular arc line is equal to a protruding length of each of the four protrusions.

6. The Hall element according to claim 3, wherein the conductor pad includes:
a first counterpart portion, disposed proximate to the central portion;
four second counterpart portions, disposed proximate to the four protrusions respectively; and
four conductor connection portions, each respective second counterpart portion of the four second counterpart portions being connected to the first counterpart portion by a respective conductor connection portion of the four conductor connection portions.

7. The Hall element according to claim 1, wherein the Hall sensing layer includes at least one of a NWELL layer, a T-well (TWELL) layer, a DNW layer, a RW layer, a P plus (PP) layer and an N plus (NP) layer.

8. The Hall element according to claim 1, wherein the blocking layer includes at least one of a PP layer, a RW layer and a NP layer.

9. The Hall element according to claim 7, wherein the blocking layer includes at least one of a PP layer, a RW layer and a NP layer.

10. The Hall element according to claim 1, wherein each of a length and a width of the Hall sensing layer is 30 μm to 270 μm.

11. A Hall sensor, comprising the Hall element, wherein the Hall element includes:
a substrate;
a Hall-sensing layer, disposed on the substrate;
a plurality of electrodes, connected to the Hall-sensing layer;
a blocking layer, disposed on a side of the Hall-sensing layer facing away from the substrate and covering the Hall-sensing layer; and
a conductor pad, disposed on a side of the blocking layer facing away from Hall-sensing layer and configured to be grounded or connected to a predetermined voltage.

12. The Hall sensor according to claim 11, wherein in response to the Hall-sensing layer being a N-well (NWELL) layer or a deep N-well (DNW) layer, the conductor pad is configured to be grounded, and in response to the Hall-sensing layer being a RW layer, the conductor pad is configured to be connected to the predetermined voltage.

13. The Hall sensor according to claim 11, wherein the Hall-sensing layer includes a central portion and four protrusions, the four protrusions are arranged in a circumferential direction of the central portion and connected to the central portion to form a cross-type structure, and the four protrusions are connected to four electrodes of the plurality of electrodes respectively.

14. The Hall sensor according to claim 13, wherein the Hall-sensing layer further includes triangular connection portions, and each two adjacent protrusions of the four protrusions are connected to each other by a respective triangular connection portion of the triangular connection portions to form an octagonal structure of the Hall-sensing layer.

15. The Hall sensor according to claim 13, wherein the Hall-sensing layer further includes arc-angle connection portions, each two adjacent protrusions of the four protrusions are connected to each other by a respective arc-angle connection portion of the arc-angle connection portions, and a contour line of the respective arc-angle connection portion facing away from the central portion is a circular arc line recessed towards the central portion, wherein:
a radius of the circular arc line is equal to one-fourth of a protruding length of each of the four protrusions; or
a radius of the circular arc line is equal to one-half of a protruding length of each of the four protrusions; or
a radius of the circular arc line is equal to a protruding length of each of the four protrusions.

16. The Hall sensor according to claim 13, wherein the conductor pad includes:
a first counterpart portion, disposed proximate to the central portion;
four second counterpart portions, disposed proximate to the four protrusions respectively; and
four conductor connection portions, each respective second counterpart portion of the four second counterpart portions being connected to the first counterpart portion by a respective conductor connection portion of the four conductor connection portions.

17. The Hall sensor according to claim 11, wherein the Hall sensing layer includes at least one of a NWELL layer, a T-well (TWELL) layer, a DNW layer, a RW layer, a P plus (PP) layer and an N plus (NP) layer.

18. The Hall sensor according to claim 11, wherein the blocking layer includes at least one of a PP layer, a RW layer and a NP layer.

19. The Hall sensor according to claim 17, wherein the blocking layer includes at least one of a PP layer, a RW layer and a NP layer.

20. An electronic device, comprising the Hall sensor according to claim 11.
